(19) United States
(12) Patent Application Publication
(10) Pub. No.: US 2022/0384629 A1
(43) Pub. Date: Dec. 1, 2022

(54) SEMICONDUCTOR DEVICE

(71) Applicant: KABUSHIKI KAISHA TOSHIBA, Tokyo (JP)

(72) Inventor: Akira MUKAI, Kawasaki (JP)

(73) Assignee: KABUSHIKI KAISHA TOSHIBA, Tokyo (JP)

(21) Appl. No.: 17/643,529

(22) Filed: Dec. 9, 2021

(30) Foreign Application Priority Data
Jun. 1, 2021 (JP) 2021-092071

(51) Int. Cl. H01L 29/778; H01L 29/20; H01L 29/423

(52) U.S. Cl. CPC H01L 29/7786; H01L 29/2003; H01L 29/4236; H01L 29/7788

(57) ABSTRACT

According to one embodiment, a semiconductor device includes first to third electrodes, a semiconductor member, a first insulating member, and a compound member. The third electrode includes a first electrode portion. The first electrode portion is between the first and second electrodes. The semiconductor member includes a first semiconductor region and a second semiconductor region. The first semiconductor region includes first to fifth partial regions. The fourth partial region is between the first and third partial regions. The fifth partial region is between the third and second partial regions. The second semiconductor region includes first and second semiconductor portions. The first insulating member includes a first insulating region. The first insulating region is between the third partial region and the first electrode portion. The compound member includes a first compound region. At least a part of the first semiconductor portion dose not overlap the compound member in the second direction.

### CROSS-REFERENCE TO RELATED APPLICATIONS

This application is based upon and claims the benefit of priority from Japanese Patent Application No. 2021-092071, filed on Jun. 1, 2021; the entire contents of which are incorporated herein by reference.

### FIELD

Embodiments described herein generally relate to a semiconductor device.

### BACKGROUND

For example, in a semiconductor device such as a transistor, improvement in characteristics is desired.

### BRIEF DESCRIPTION OF THE DRAWINGS

FIG. 1 is a schematic cross-sectional view illustrating a semiconductor device according to a first embodiment;

FIG. 2 is a schematic cross-sectional view illustrating a semiconductor device according to the first embodiment;

FIG. 3 is a schematic cross-sectional view illustrating a semiconductor device according to the first embodiment; and

FIG. 4 is a schematic cross-sectional view illustrating a semiconductor device according to a second embodiment.

### DETAILED DESCRIPTION

According to one embodiment, a semiconductor device includes a first electrode, a second electrode, a third electrode, a semiconductor member, a first insulating member, and a compound member. A direction from the first electrode to the second electrode is along the first direction. The third electrode includes a first electrode portion. A position of the first electrode portion in the first direction is located between a position of the first electrode in the first direction and a position of the second electrode in the first direction. The semiconductor member includes a first semiconductor region and a second semiconductor region. The first semiconductor region includes Alₓ₁Ga₁₋ₓ₁N (0≤x1<1). The first semiconductor region includes a first partial region, a second partial region, a third partial region, a fourth partial region, and a fifth partial region. A direction from the first partial region to the first electrode, a direction from the second partial region to the second electrode, and a direction from the third partial region to the first electrode portion are along a second direction crossing the first direction. A position of the fourth partial region in the first direction is between a position of the first partial region in the first direction and a position of the third partial region in the first direction. A position of the fifth partial region in the first direction is between the position of the third partial region in the first direction and a position of the second partial region in the first direction. The second semiconductor region includes Alₓ₂Ga₁₋ₓ₂N (0<x2≤1, x1<x2). The second semiconductor region includes a first semiconductor portion and a second semiconductor portion. A direction from the fourth partial region to the first semiconductor portion is along the second direction. A direction from the fifth partial region to the second semiconductor portion is along the second direction. The first insulating member includes a first insulating region. The first insulating region is located between the third partial region and the first electrode portion in the second direction. At least a part of the first insulating region is located between the fourth partial region and the fifth partial region in the first direction. The compound member includes Al, Si and oxygen. The compound member includes a first compound region. At least a part of the first compound region is located between the fourth partial region and at least a part of the first insulating region in the first direction. At least a part of the first semiconductor portion does not overlap the compound member in the second direction.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

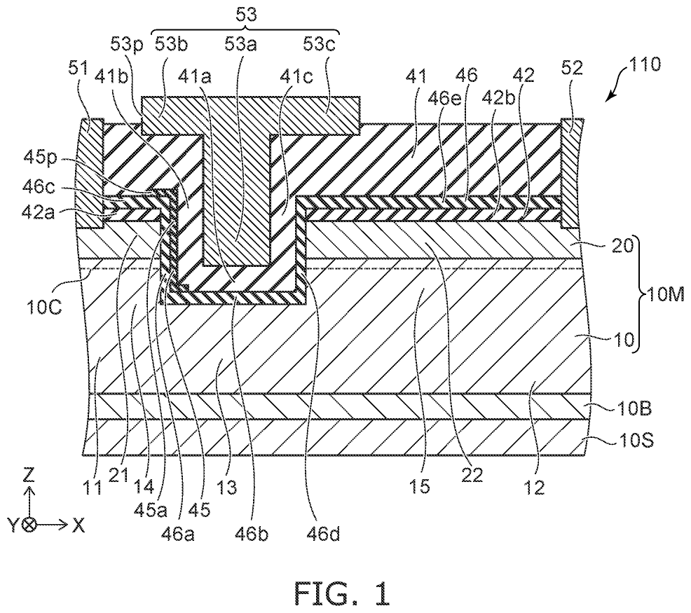

FIG. 1 is a schematic cross-sectional view illustrating a semiconductor device according to the first embodiment.

As shown in FIG. 1, the semiconductor device 110 according to the embodiment includes a first electrode 51, a second electrode 52, a third electrode 53, a semiconductor member 10M, a first insulating member 41, and a compound member 45.

A direction from the first electrode 51 to the second electrode 52 is along a first direction. The first direction is taken as an X-axis direction. A direction perpendicular to the X-axis direction is defined as a Z-axis direction. The direction perpendicular to the X-axis direction and the Z-axis direction is defined as the Y-axis direction.

The third electrode 53 includes a first electrode portion 53a. A position of the first electrode portion 53a in the first direction (X-axis direction) is located between a position of the first electrode 51 in the first direction and a position of the second electrode 52 in the first direction. For example, at least a part of the first electrode portion 53a of the third electrode 53 is located between the first electrode 51 and the second electrode 52 in the first direction.

A semiconductor member 10M includes a first semiconductor region 10 and a second semiconductor region 20. The first semiconductor region 10 includes Alₓ₁Ga₁₋ₓ₁N (0≤x1<1). The composition ratio x1 is, for example, not less than 0 and not more than 0.1. In one example, the first semiconductor region 10 is a GaN layer.

The first semiconductor region 10 includes a first partial region 11, a second partial region 12, a third partial region 13, a fourth partial region 14, and a fifth partial region 15. A direction from the first partial region 11 to the first electrode 51, a direction from the second partial region 12 to the second electrode 52, and a direction from the third partial region 13 to the first electrode portion 53a are along a second direction. The second direction crosses the first direction. The second direction is, for example, the Z-axis direction.

A position of the fourth partial region 14 in the first direction (X-axis direction) is located between the position of the first partial region 11 in the first direction and the position of the third partial region 13 in the first direction. A position of the fifth partial region 15 in the first direction is located between the position of the third partial region 13 in the first direction and the position of the second partial region 12 in the first direction.

The first partial region 11 is a region of the first semiconductor region 10 that overlaps the first electrode 51 in the Z-axis direction. The second partial region 12 is a region of the first semiconductor region 10 that overlaps the second electrode 52 in the Z-axis direction. The third partial region 13 is a region of the first semiconductor region 10 that overlaps the third electrode 53 in the Z-axis direction. The boundaries between the first to fifth partial regions 11 to 15 do not have to be clear.

The second semiconductor region 20 includes Alₓ₂Ga₁₋ₓ₂N (0<x2<1, x1<x2). The composition ratio x2 is, for example, not less than 0.15 and not more than 0.3. The second semiconductor region 20 is, for example, an AlGaN layer.

The second semiconductor region 20 includes a first semiconductor portion 21 and a second semiconductor portion 22. A direction from the fourth partial region 14 to the first semiconductor portion 21 is along the second direction (for example, the Z-axis direction). A direction from the fifth partial region 15 to the second semiconductor portion 22 is along the second direction.

In this example, the semiconductor member 10M includes a base body 10S and a nitride semiconductor layer 10B. The nitride semiconductor layer 10B is provided on the base body 10S. The first semiconductor region 10 is provided on the nitride semiconductor layer 10B. The second semiconductor region 20 is provided on the first semiconductor region 10.

The first insulating member 41 includes a first insulating region 41a. The first insulating region 41a is located between the third partial region 13 and the first electrode portion 53a in the second direction (Z-axis direction). At least a part of the first insulating region 41a is located between the fourth partial region 14 and the fifth partial region 15 in the first direction (X-axis direction).

The compound member 45 includes Al, Si and oxygen. In one example, the compound member 45 is, for example, a SiAlO film. The compound member 45 may further include nitrogen. In one example, the compound member 45 is, for example, a SiAlON film.

The compound member 45 includes a first compound region 45a. At least a part of the first compound region 45a is located between the fourth partial region 14 and at least a part of the first insulating region 41a in the first direction (X-axis direction). At least a part of the first semiconductor portion 21 does not overlap the compound member 45 in the second direction (Z-axis direction).

For example, in the first semiconductor region 10, the carrier region 10C is formed in a portion facing the second semiconductor region 20. The carrier region 10C is, for example, a two-dimensional electron gas.

The current flowing between the first electrode 51 and the second electrode 52 can be controlled by a potential of the third electrode 53. The first electrode 51 functions as, for example, a source electrode. The second electrode 52 functions as, for example, a drain electrode. The third electrode 53 functions as, for example, a gate electrode. The semiconductor device 110 is, for example, a transistor. The semiconductor device 110 is, for example, HEMT (High Electron Mobility Transistor). A recess gate structure is applied to the semiconductor device 110.

In the embodiment, the compound member 45 as described above is provided. The first compound region 45a of the compound member 45 is provided at a recess side portion (including a recess corner portion) of the gate electrode. The first compound region 45a forms, for example, a dipole. Thereby, for example, the electric field distribution can be controlled and the threshold voltage can be increased.

For example, in a reference example in which the compound member 45 is provided on the entire second semiconductor region 20 (the entire first semiconductor portion 21), the compound member 45 tends to adversely affect the carrier region 10C. For example, the current becomes difficult to flow and the ON-resistance becomes high.

In the embodiment, the compound member 45 is not provided on, for example, the entire second semiconductor region 20 (the entire first semiconductor portion 21). As a result, the influence of the compound member 45 on the carrier region 10C is suppressed. Thereby, for example, a low ON-resistance can be maintained. In the embodiment, a high threshold voltage can be stably obtained. In the embodiments, low ON-resistance is obtained. In the embodiments, it is possible to provide a semiconductor device whose characteristics can be improved.

When the compound member 45 is a SiAlO film, the atomic concentration of Al is set to [Al] and the atomic concentration of Si is set to [Si] in the compound member 45. At this time, the cation composition ratio α of Al in the compound member 45 is represented by [Al]/([Si]+[Al]). In the embodiment, the cation composition ratio α of Al is preferably not less than 0.1 and not more than 0.4. When the cationic composition ratio α of Al is less than 0.1, it becomes difficult to obtain a high threshold voltage. When the cation composition ratio α of Al exceeds 0.4, dipoles having opposite polarities (opposite directions) are likely to occur.

When the compound member 45 is a SiAlON film, the atomic concentration of Al is set to [Al] and the atomic concentration of Si is set to [Si] in the compound member 45. Also in this case, the cation composition ratio α of Al in the compound member 45 is represented by [Al]/([Si]+[Al]). In the compound member 45, the atomic concentration of nitrogen (N) is set to be [N], and the atomic concentration of oxygen (O) is set to be [O]. At this time, the anion composition ratio β of N in the compound member 45 is represented by [N]/([N]+[O]).

In the embodiment, when the compound member 45 is a SiAlON film, the cation composition ratio α of Al is preferably more than 0 and not more than 0.9. The anion composition ratio β of nitrogen (N) is preferably more than 0 and not more than 0.7. Further, it is preferable that the cation composition ratio α of Al and the anion composition ratio β of N satisfy following relationship:

−0.6α+1<β<−0.5α+1.2.

When the cation composition ratio α of Al exceeds 0.9, dipoles having opposite polarities (opposite directions) are likely to occur. When the anion composition ratio β of N exceeds 0.7, dipoles are less likely to occur. When β≤(−0.6α+1), it becomes difficult to obtain a high threshold voltage. When (−0.5α+1.2)≤β, dipoles of opposite polarity (reverse direction) are likely to occur.

In one example, the first insulating member 41 includes silicon and oxygen. The first insulating member 41 includes, for example, silicon oxide (for example, SiO₂). The first insulating member 41 does not include Al. Alternatively, a concentration of Al in the first insulating member 41 is lower than a concentration of Al in the compound member 45.

The first insulating member 41 may be provided on the second semiconductor region 20. A dipole is not substantially formed in the first insulating member 41. The first insulating member 41 does not substantially have an adverse effect on the carrier region 10C.

As shown in FIG. 1, the first insulating member 41 may further include a second insulating region 41b. The second insulating region 41b is located between the first semiconductor portion 21 and the first electrode portion 53a in the first direction (X-axis direction). A part of the first compound region 45a is located between the first semiconductor portion 21 and the second insulating region 41b in the first direction (X-axis direction).

As shown in FIG. 1, in this example, a part of the first compound region 45a is located between the third partial region 13 and a part of the second insulating region 41b in the second direction (Z-axis direction). A part of the first compound region 45a may be provided at the bottom of the recess.

As shown in FIG. 1, the third electrode 53 may further include the second electrode portion 53b. The first semiconductor portion 21 is located between the fourth partial region 14 and the second electrode portion 53b in the second direction (Z-axis direction). For example, at least a part of the second electrode portion 53b does not overlap the compound member 45 in the second direction (Z-axis direction). The adverse effect of the compound member 45 on the carrier region 10C can be suppressed by, for example, the potential of the second electrode portion 53b.

For example, the second electrode portion 53b includes a first electrode end portion 53p. The first electrode end portion 53p is an end portion of the third electrode 53 on the side of the first electrode 51. The compound member 45 includes a first compound end portion 45p. The first compound end portion 45p is an end portion of the first compound region 45a on the side of the first electrode 51. A distance along the first direction (X-axis direction) between the first electrode 51 and the first electrode end portion 53p is shorter than a distance along the first direction between the first electrode 51 and the first compound end portion 45p. The first electrode end portion 53p protrudes toward the first electrode 51 with respect to the first compound end portion 45p.

As shown in FIG. 1, the semiconductor device 110 may further include a nitride member 46. The nitride member 46 includes Alₓ₃Ga₁₋ₓ₃N (0<x3≤1, x2<x3). The composition ratio x3 is, for example, not less than 0.8 and not more than 1. The nitride member 46 is, for example, an AlN film.

The nitride member 46 includes a first nitride region 46a and a second nitride region 46b. The first nitride region 46a is located between the fourth partial region 14 and the first compound region 45a in the first direction (X-axis direction). The second nitride region 46b is located between the third partial region 13 and the first insulating region 41a in the second direction (Z-axis direction). The nitride member 46 makes it easy to stably obtain a low ON-resistance.

As shown in FIG. 1, the nitride member 46 may further include a third nitride region 46c. The first semiconductor portion 21 is located between the fourth partial region 14 and the third nitride region 46c in the second direction (Z-axis direction). At least a part of the third nitride region 46c does not overlap the compound member 45 in the second direction (Z-axis direction).

When the third electrode 53 includes the second electrode portion 53b, the first semiconductor portion 21 is located between the fourth partial region 14 and the second electrode portion 53b in the second direction (Z-axis direction). A part of the compound member 45 is located between a part of the third nitride region 46c and a part of the second electrode portion 53b in the second direction (Z-axis direction).

As shown in FIG. 1, the semiconductor device 110 may include a second insulating member 42. The second insulating member 42 includes a first insulating portion 42a. The first insulating portion 42a is located between the first semiconductor portion 21 and the third nitride region 46c in the second direction (Z-axis direction).

The first insulating member 41 includes silicon and oxygen. The first insulating member 41 includes, for example, silicon oxide. The second insulating member 42 includes, for example, silicon and nitrogen. The second insulating member 42 includes, for example, silicon nitride.

For example, the first insulating member 41 does not include nitrogen, and the second insulating member 42 does not include oxygen. Alternatively, a concentration of nitrogen in the first insulating member 41 is lower than a concentration of nitrogen in the second insulating member 42, and a concentration of oxygen in the second insulating member 42 is lower than a concentration of oxygen in the first insulating member 41. Such a second insulating member 42 stabilizes the characteristics of the second semiconductor region 20.

For example, the first insulating portion 42a is in contact with the first semiconductor portion 21. The third nitride region 46c is in contact with the first insulating portion 42a. A part of the first insulating member 41 is in contact with the third nitride region 46c.

As shown in FIG. 1, the first insulating member 41 may include a third insulating region 41c. The third insulating region 41c is located between the first electrode portion 53a and the second semiconductor portion 22 in the X-axis direction. The nitride member 46 may include a fourth nitride region 46d and a fifth nitride region 46e. The fourth nitride region 46d is located between the third insulating region 41c and the fifth partial region 15 in the first direction (X-axis direction). A part of the fourth nitride region 46d is located between the third insulating region 41c and the second semiconductor portion 22 in the first direction (X-axis direction). The second semiconductor portion 22 is located between the fifth partial region 15 and the fifth nitride region 46e in the second direction (Z-axis direction).

The second insulating member 42 may include a second insulating portion 42b. The second semiconductor portion 22 is located between the fifth partial region 15 and the second insulating portion 42b. The fifth nitride region 46e is located between the second insulating portion 42b and the first insulating member 41 in the Z-axis direction.

As shown in FIG. 1, the third electrode 53 may include a third electrode portion 53c. A part of the second semiconductor portion 22 is located between the fifth partial region 15 and the third electrode portion 53c in the second direction (Z-axis direction).

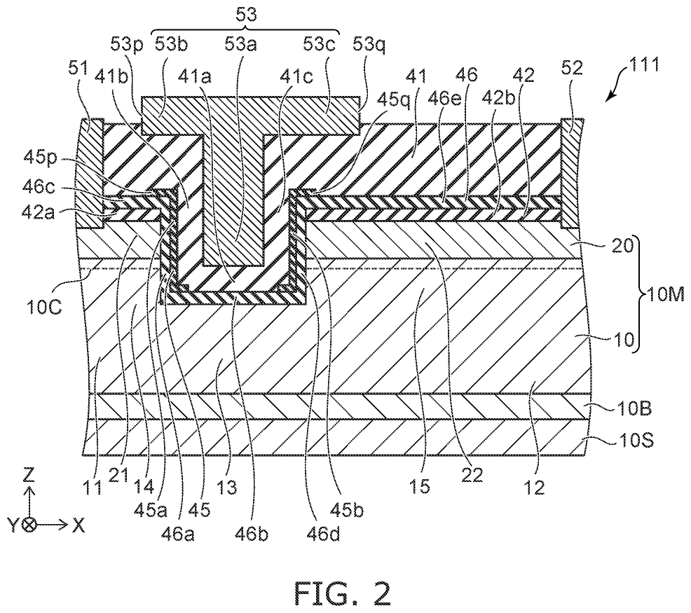

FIG. 2 is a schematic cross-sectional view illustrating a semiconductor device according to the first embodiment.

As shown in FIG. 2, the semiconductor device 111 according to the embodiment also includes the first electrode 51, the second electrode 52, the semiconductor member 10M, the first insulating member 41, and the compound member 45. In the semiconductor device 111, the compound member 45 includes a second compound region 45b. Other configurations of the semiconductor device 111 may be the same as the configuration of the semiconductor device 110.

At least a part of the second compound region 45b is located between at least a part of the first insulating region 41a and the fifth partial region 15 in the first direction (X-axis direction). At least a part of the second semiconductor portion 22 does not overlap the compound member 45 in the second direction (Z-axis direction).

For example, the first insulating member 41 includes a third insulating region 41c. The third insulating region 41c is located between the first electrode portion 53a and the second semiconductor portion 22 in the first direction (X-axis direction). A part of the second compound region 45b is located between the third insulating region 41c and the second semiconductor portion 22 in the first direction (X-axis direction).

The second compound region 45b makes it possible to obtain a high threshold voltage more reliably. In the embodiment, it is possible to provide a semiconductor device whose characteristics can be improved.

For example, a part of the second compound region 45b is located between the third partial region 13 and a part of the third insulating region 41c in the second direction (Z-axis direction).

For example, the third electrode 53 includes a third electrode portion 53c. The second semiconductor portion 22 is located between the fifth partial region 15 and the third electrode portion 53c in the second direction (Z-axis direction). At least a part of the third electrode portion 53c does not overlap the compound member 45 in the second direction.

The third electrode portion 53c includes a second electrode end portion 53q. The second compound region 45b includes a second compound end 45q. A distance along the first direction (X-axis direction) between the second electrode end portion 53q and the second electrode 52 is shorter than a distance along the first direction between the second compound end 45q and the second electrode 52.

As shown in FIG. 2, the semiconductor device 111 may also include the nitride member 46. The nitride member 46 includes Alₓ₃Ga₁₋ₓ₃N (0<x3≤1, x2<x3). The nitride member 46 includes the first nitride region 46a, the second nitride region 46b, the third nitride region 46c, the fourth nitride region 46d, and the fifth nitride region 46e.

The first nitride region 46a is located between the fourth partial region 14 and the first compound region 45a in the first direction (X-axis direction). The second nitride region 46b is located between the third partial region 13 and the first insulating region 41a in the second direction (Z-axis direction). The first semiconductor portion 21 is located between the fourth partial region 14 and the third nitride region 46c in the second direction (Z-axis direction). At least a part of the third nitride region 46c does not overlap the compound member 45 in the second direction (Z-axis direction). The fourth nitride region 46d is located between the second compound region 45b and the fifth partial region 15 in the first direction (X-axis direction). At least a part of the fifth nitride region 46e does not overlap the compound member 45 in the second direction (Z-axis direction).

For example, the third electrode 53 includes the third electrode portion 53c. The second semiconductor portion 22 is located between the fifth partial region 15 and the third electrode portion 53c in the second direction. A part of the compound member 45 (second compound region 45b) is located between a part of the fifth nitride region 46e and a part of the third electrode portion 53c in the second direction.

As shown in FIG. 2, the semiconductor device 111 may also include the second insulating member 42. The second insulating member 42 includes the first insulating portion 42a and the second insulating portion 42b. The first insulating portion 42a is located between the first semiconductor portion 21 and the third nitride region 46c in the second direction (Z-axis direction). The second insulating portion 42b is located between the second semiconductor portion 22 and the fifth nitride region 46e in the second direction. As described above, the first insulating member 41 includes silicon and oxygen. The second insulating member 42 includes silicon and nitrogen. For example, the first insulating member 41 does not include nitrogen and the second insulating member 42 does not include oxygen. Alternatively, the concentration of nitrogen in the first insulating member 41 is lower than the concentration of nitrogen in the second insulating member 42, and the concentration of oxygen in the second insulating member 42 is lower than the concentration of oxygen in the first insulating member 41.

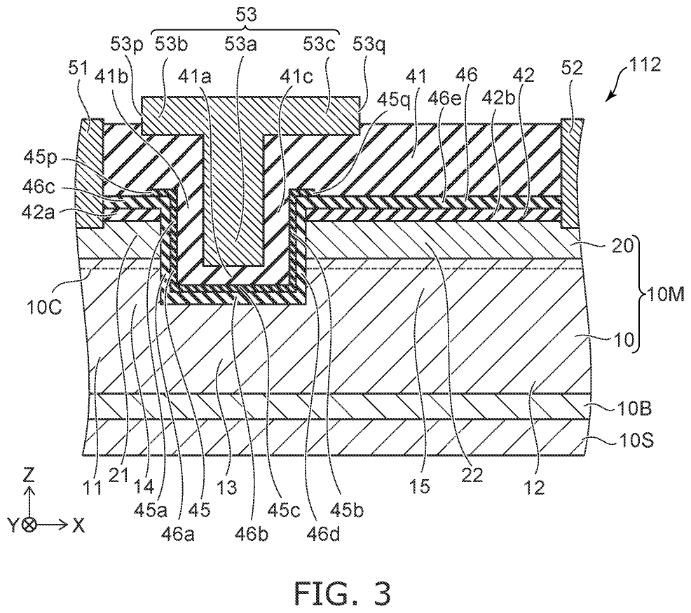

FIG. 3 is a schematic cross-sectional view illustrating a semiconductor device according to the first embodiment.

As shown in FIG. 3, the semiconductor device 112 according to the embodiment also includes the first electrode 51, the second electrode 52, the semiconductor member 10M, the first insulating member 41, and the compound member 45. In the semiconductor device 112, the compound member 45 includes a third compound region 45c. Other configurations of the semiconductor device 112 may be the same as the configuration of the semiconductor device 111.

The third compound region 45c is located between the third partial region 13 and the first insulating region 41a in the second direction (Z-axis direction). A high threshold voltage is obtained more reliably by the third compound region 45c. In the embodiment, it is possible to provide a semiconductor device whose characteristics can be improved.

The boundary between the first to third compound regions 45a to 45c may be unclear. The third compound region 45c may be continuous with the first compound region 45a. The third compound region 45c may be continuous with the second compound region 45b. The third compound region 45c may not be provided, and the second compound region 45b may be continuous with the first compound region 45a.

In the first embodiment, the distance between the first electrode 51 and the third electrode 53 along the first direction (X-axis direction) is shorter than the distance between the third electrode 53 and the second electrode 52 in the first direction (X-axis direction). In this case, the first electrode 51 functions as a source electrode, and the second electrode 52 functions as a drain electrode.

### Second Embodiment

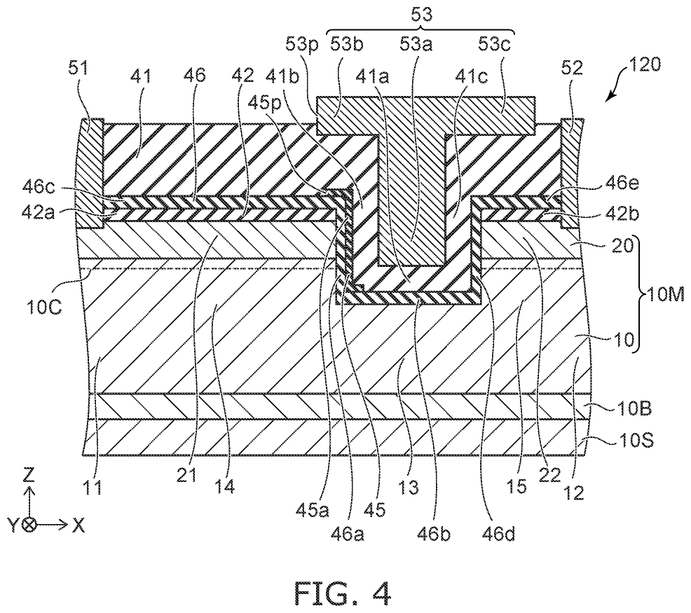

FIG. 4 is a schematic cross-sectional view illustrating a semiconductor device according to a second embodiment.

As shown in FIG. 4, the semiconductor device 120 according to the embodiment also includes the first electrode 51, the second electrode 52, the semiconductor member 10M, the first insulating member 41, and the compound member 45. In the semiconductor device 120, the distance along the first direction (X-axis direction) between the first electrode 51 and the third electrode 53 along the first direction (X-axis direction) is longer than the distance between the third electrode 53 and the second electrode 52 along the first direction (X-axis direction). In the semiconductor device 120, the first electrode 51 functions as a drain electrode, and the second electrode 52 functions as a source electrode. Also in the semiconductor device 120, the compound member 45 including the first compound region 45a is provided. For example, a high threshold voltage can be obtained. A low ON-resistance is obtained. In the embodiment, it is possible to provide a semiconductor device whose characteristics can be improved.

In the embodiment, the thickness of the compound member 45 is, for example, not less than 1 nm and not more than 5 nm. The thickness of the nitride member 46 is, for example, not less than 1 nm and not more than 5 nm. The thickness of the second insulating member 42 is, for example, not less than 5 nm and not more than 20 nm. Information on the concentration of elements (or composition ratio) in the member can be obtained by, for example, SIMS (Secondary Ion Mass Spectrometry).

At least one of the first electrode 51 and the second electrode 52 includes, for example, at least one selected from the group consisting of Ti and Al. The third electrode 53 includes, for example, at least one selected from the group consisting of TiN, Ni and W.

In one example according to the embodiment, the distance between the third electrode 53 and the second electrode 52 along the X-axis direction is, for example, not less than 15 μm and not more than 20 μm. In one example, the recess depth of the recess gate structure (for example, the distance from the upper surface of the second semiconductor region 20 to the bottom surface of the first insulating region 41a, or the distance from the bottom surface of the second semiconductor region 20 to the bottom surface of the second nitride region 46b) is not less than 150 nm. As a result, a stable threshold voltage can be easily obtained. In one example, the thickness of the second semiconductor region 20 (a length along the Z-axis direction) is, for example, not more than 20 nm and not more than 40 nm. The thickness of the first insulating member 41 (for example, the length of the first insulating region 41a along the Z-axis direction) is, for example, not less than 20 nm and not more than 60 nm.

According to the embodiments, it is possible to provide a semiconductor device whose characteristics can be improved.

In the specification, “nitride semiconductor” includes all compositions of semiconductors of the chemical formula BₓIn_{y}Al_{z}Ga_{1-x-y-z}N (0≤x≤1, 0≤y≤1, 0≤z≤1, and x+y+z≤1) for which the composition ratios x, y, and z are changed within the ranges respectively. “Nitride semiconductor” further includes group V elements other than N (nitrogen) in the chemical formula recited above, various elements added to control various properties such as the conductivity type and the like, and various elements included unintentionally.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in semiconductor devices such as electrodes, semiconductor members, insulating members, compound members, nitride members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode, a direction from the first electrode to the second electrode being along the first direction;
a third electrode including a first electrode portion, a position of the first electrode portion in the first direction being located between a position of the first electrode in the first direction and a position of the second electrode in the first direction;
a semiconductor member including a first semiconductor region and a second semiconductor region,
the first semiconductor region including Alₓ₁Ga₁₋ₓ₁N (0≤x1<1), the first semiconductor region including a first partial region, a second partial region, a third partial region, a fourth partial region, and a fifth partial region, a direction from the first partial region to the first electrode, a direction from the second partial region to the second electrode, and a direction from the third partial region to the first electrode portion being along a second direction crossing the first direction, a position of the fourth partial region in the first direction being between a position of the first partial region in the first direction and a position of the third partial region in the first direction, a position of the fifth partial region in the first direction being between the position of the third partial region in the first direction and a position of the second partial region in the first direction,
the second semiconductor region including Alₓ₂Ga₁₋ₓ₂N (0<x2≤1, x1<x2), the second semiconductor region including a first semiconductor portion and a second semiconductor portion, a direction from the fourth partial region to the first semiconductor portion being along the second direction;
a first insulating member including a first insulating region, the first insulating region being located between the third partial region and the first electrode portion, at least a part of the first insulating region being located between the fourth partial region and the fifth partial region in the first direction; and
a compound member including Al, Si and oxygen, the compound member including a first compound region, at least a part of the first compound region being located between the fourth partial region and at least a part of the first insulating region in the first direction, at least a part of the first semiconductor portion not overlapping the compound member in the second direction.

2. The device according to claim 1, wherein
in the compound member, an atomic concentration of Al is represented by [Al] and an atomic concentration of Si is represented by [Si],
a cation composition ratio α of Al in the compound member is represented by [Al]/([Si]+[Al]),
the cation composition ratio α of Al is not less than 0.1 and more than 0.4.

3. The device according to claim 1, wherein the compound member further includes nitrogen (N).

4. The device according to claim 3, wherein
in the compound member, an atomic concentration of Al is represented by [Al] and an atomic concentration of Si is represented by [Si],
a cation composition ratio α of Al in the compound member is represented by [Al]/([Si]+[Al]),
in the compound member, an atomic concentration of nitrogen (N) is represented by [N] and an atomic concentration of oxygen (O) is represented by [O],
an anion composition ratio β of N in the compound member is represented by [N]/([N]+[O]),
the cation composition ratio α of the Al is not more than 0.9,
the anion composition ratio β of the N is not more than 0.7,
the cation composition ratio α of Al and the anion composition ratio β of N satisfy:
−0.6α+1<β<−0.5α+1.2.

5. The device according to claim 1, wherein
the first insulating member further includes a second insulating region,
the second insulating region is located between the first semiconductor portion and the first electrode portion in the first direction, and
a part of the first compound region is located between the first semiconductor portion and the second insulating region in the first direction.

6. The device according to claim 5, wherein a part of the first compound region is located between the third partial region and a part of the second insulating region in the second direction.

7. The device according to claim 5, wherein
the third electrode further includes a second electrode portion,
the first semiconductor portion is located between the fourth partial region and the second electrode portion in the second direction, and
at least a part of the second electrode portion does not overlap the compound member in the second direction.

8. The device according to claim 5, wherein
the third electrode further includes a second electrode portion,
the first semiconductor portion is located between the fourth partial region and the second electrode portion in the second direction,
the second electrode portion includes a first electrode end portion,
the first compound member includes a first compound end portion,
a distance between the first electrode and the first electrode end portion along the first direction is shorter than a distance between the first electrode and the first compound end portion along the first direction.

9. The device according to claim 1, further comprising a nitride member including Alₓ₃Ga₁₋ₓ₃N (0<x3≤1, x2<x3),
the nitride member includes a first nitride region and a second nitride region,
the first nitride region is located between the fourth partial region and the first compound region in the first direction, and
the second nitride region is located between the third partial region and the first insulating region in the second direction.

10. The device according to claim 9, wherein
the nitride member further includes a third nitride region,
the first semiconductor portion is located between the fourth partial region and the third nitride region in the second direction, and
at least a part of the third nitride region does not overlap the compound member in the second direction.

11. The device according to claim 10, wherein
the third electrode further includes a second electrode portion,
the first semiconductor portion is located between the fourth partial region and the second electrode portion in the second direction, and
a part of the compound member is located between a part of the third nitride region and a part of the second electrode portion in the second direction.

12. The device according to claim 10, further comprising a second insulating member including a first insulating portion,
the first insulating portion is located between the first semiconductor portion and the third nitride region in the second direction,
the first insulating member includes silicon and oxygen,
the second insulating member includes silicon and nitrogen,
the first insulating member does not include nitrogen and the second insulating member does not include oxygen, or
a concentration of nitrogen in the first insulating member is lower than a concentration of nitrogen in the second insulating member, and a concentration of oxygen in the second insulating member is lower than a concentration of oxygen in the first insulating member.

13. The device according to claim 12, wherein
the first insulating portion is in contact with the first semiconductor portion,
the third nitride region is in contact with the first insulating portion, and
a part of the first insulating member is in contact with the third nitride region.

14. The device according to claim 1, wherein
the first insulating member includes silicon and oxygen, and
the first insulating member does not include Al, or a concentration of Al in the first insulating member is lower than a concentration of Al in the compound member.

15. The device according to claim 1, wherein
the compound member includes a second compound region,
at least a part of the second compound region is located between at least a part of the first insulating region and a fifth partial region in the first direction.
at least a part of the second semiconductor portion does not overlap the compound member in the second direction.

16. The device according to claim 15, wherein
the first insulating member further includes a third insulating region,
the third insulating region is located between the first electrode portion and the second semiconductor portion in the first direction, and
a part of the second compound region is located between the third insulating region and the second semiconductor portion in the first direction.

17. The device according to claim 16, wherein
a part of the second compound region is located between the third partial region and a part of the third insulating region in the second direction.

18. The device according to claim 1, wherein
the third electrode further includes a third electrode portion,
the second semiconductor portion is located between the fifth partial region and the third electrode portion in the second direction,
at least a part of the third electrode portion does not overlap the compound member in the second direction.

19. The device according to claim 15, further comprising a nitride member including Alₓ₃Ga₁₋ₓ₃N (0<x3≤1, x2<x3),
the nitride member including a first nitride region, a second nitride region, a third nitride region, a fourth nitride region, and a fifth nitride region,
the first nitride region is located between the fourth partial region and the first compound region in the first direction,
the second nitride region is located between the third partial region and the first insulating region in the second direction,
the first semiconductor portion is located between the fourth partial region and the third nitride region in the second direction,
at least a part of the third nitride region does not overlap the compound member in the second direction,
the fourth nitride region is located between the second compound region and the fifth partial region in the first direction, and
at least a part of the fifth nitride region does not overlap the compound member in the second direction.

20. The device according to claim 19, further comprising a second insulating member including a first insulating portion and a second insulating portion,
the first insulating portion being located between the first semiconductor portion and the third nitride region in the second direction,
the second insulating portion being located between the second semiconductor portion and the fifth nitride region in the second direction,
the first insulating member including silicon and oxygen,
the second insulating member including silicon and nitrogen,
the first insulating member does not include nitrogen and the second insulating member does not include oxygen, or
a concentration of nitrogen in the first insulating member is lower than a concentration of nitrogen in the second insulating member, and a concentration of oxygen in the second insulating member is lower than a concentration of oxygen in the first insulating member.
